(19) United States
(12) Patent Application Publication
(10) Pub. No.: US 2020/0088674 A1
(43) Pub. Date: Mar. 19, 2020

(54) THIN FILM TRANSISTOR GAS SENSOR

(71) Applicant: Sumitomo Chemical Company Limited, Tokyo (JP)

(72) Inventors: Daniel Tobjork, Cambridgeshire (GB); Nicholas Dartnell, Eltisley (GB); Christopher Newsome, St. Ives (GB)

(73) Assignee: Sumitomo Chemical Company Limited, Tokyo (JP)

(21) Appl. No.: 16/576,495

(22) Filed: Sep. 19, 2019

(30) Foreign Application Priority Data
Sep. 19, 2018 (GB) 1815239.7

(51) Int. Cl. G01N 27/414; H01L 29/49

(52) U.S. Cl. CPC G01N 27/4141; G01N 27/4148; H01L 29/4908

(57) ABSTRACT

A thin film transistor gas sensor and a method of sensing a target gas using the thin-film transistor gas sensor. A gate electrode of the thin film transistor gas sensor has a conductive layer with a surface in direct contact with a dielectric layer of the thin-film transistor. The work function at the surface changes when it comes into contact with a target gas, for example the gate electrode may be formed from gold and have a surface work function that changes when the surface of the gold gate electrode comes into contact with a gas, such as 1-methylcyclopropene.

### RELATED APPLICATIONS

This application claims foreign priority benefits under 35 U.S.C. § 119(a)-(d) or 35 U.S.C. § 365(b) of British application number GB 1815239.7, filed Sep. 19, 2018, the entirety of which is incorporated herein by reference.

### BACKGROUND

Embodiments of the present disclosure relate to thin film transistor (TFT) gas sensors. In some embodiments the gas sensor has a gate electrode containing gold. In some embodiments, the gas sensor is configured to sense 1-methylcyclopropene.

Thin film transistors have been previously used as gas sensors. For example, such use of thin film transistors as gas sensors is described in Feng et al., “Unencapsulated Air-stable Organic Field Effect Transistor by All Solution Processes for Low Power Vapor Sensing,” SCIENTIFIC REPORTS 6:20671 DOI: 10.1038/srep20671.

In thin film transistor gas sensors, a semiconductor layer of the transistor is able to interact with the atmosphere and/or a gas sample. An electrical output from the thin film transistor can be correlated to the concentration of the gas.

### SUMMARY

A summary of aspects of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects and/or a combination of aspects that may not be set forth.

The present inventors have surprisingly found that the presence or absence of a target gas, and/or the concentration of a target gas in an environment can be sensed with a thin film transistor (TFT) gas sensor in which the gate electrode of the TFT comprises or consists of a conducting material at the gate electrode—gate dielectric interface having a work function, which changes upon exposure to the target gas.

In some embodiments there is provided a method of sensing a target gas in an environment including the step of measuring a response of a thin-film transistor gas sensor in the environment. The thin-film transistor gas sensor includes a semiconducting layer made from a semiconductor, with a source electrode and a drain electrode defining a channel in the semiconducting layer. The thin-film transistor gas sensor further includes a gate electrode with a dielectric layer disposed between the gate electrode and the semiconductor layer. The gate electrode includes a conducting layer having a surface in direct contact with the gate dielectric. In embodiments of the present disclosure, the work function of the conducting layer at the surface in direct contact with the gate dielectric changes upon exposure to the target gas.

In some embodiments there is provided a thin film transistor gas sensor for detecting and/or measuring a concentration of a target gas in an atmosphere. The thin-film transistor gas sensor includes a semiconducting layer made from a semiconductor, with a source electrode and a drain electrode defining a channel in the semiconducting layer. The thin-film transistor gas sensor further includes a gate electrode with a dielectric layer disposed between the gate electrode and the semiconductor layer.

In some embodiments, the gate electrode has a conducting layer having a surface in direct contact with the dielectric layer, wherein a work function of the surface is configured to change when contacted by the target gas. A processor may be configured to process the presence and/or the concentration of the target from an output of the thin film transistor gas sensor.

It will be understood that, upon exposure to a target gas, the work function of any surface of the conducting gate electrode layer in gas communication with a target gas may change, whereas the work function of any part of the gate electrode layer that is not in gas communication with the target gas may be unchanged.

Ethylene produced by plants can accelerate ripening of climacteric fruit, the opening of flowers, and the shedding of plant leaves. 1-methylcyclopropene (1-MCP) is known for use in inhibiting such processes. In some embodiments of the present disclosure, concentration of 1-MCP in an environment in which plants, crops and/or fruit are being stored, such as a warehouse in which harvested fruit is treated with 1-MCP and stored, is measured.

In some embodiments, the target gas is 1-MCP. In some embodiments, the gate electrode comprises or consists of elemental gold. In some embodiments, the thin-film transistor gas sensor is a bottom-gate thin film transistor gas sensor. In some embodiments, the semiconductor is an organic semiconductor.

In some embodiments, the thin film transistor gas sensor is part of a gas sensor system, which further contains a reference thin film transistor.

### DESCRIPTION OF THE DRAWINGS

The present disclosure is described in conjunction with the appended figures. It is emphasized that, in accordance with the standard practice in the industry, various features are not drawn to scale. In fact, the dimensions of the various features may be arbitrarily increased or reduced for clarity of discussion.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 illustrates a bottom gate, bottom contact thin film transistor gas sensor according to some embodiments of the present disclosure;

FIG. 2 illustrates a bottom gate, top contact organic thin film transistor gas sensor according to some embodiments of the present disclosure;

FIG. 3 illustrates a top gate organic thin film transistor gas sensor according to some embodiments of the present disclosure;

FIG. 4 shows the photoelectron spectra of a gold surface before and after exposure to 1-MCP;

FIG. 5 is a graph of current change vs. time following exposure to an environment containing 1-MCP for a top gate organic thin film transistor gas sensor according to an embodiment and an organic thin film transistor in which the surface of the gate electrode has been altered; and

FIG. 6 is a graph of the square root of drain current vs. gate voltage of the device of FIG. 5 before and after exposure to 1-MCP

### DETAILED DESCRIPTION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, electromagnetic, or a combination thereof. Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

The techniques introduced here can be embodied as special-purpose hardware (e.g., circuitry), as programmable circuitry appropriately programmed with software and/or firmware, or as a combination of special-purpose and programmable circuitry. Hence, embodiments may include a machine-readable medium having stored thereon instructions which may be used to program a computer (or other electronic devices) to perform a process. The machine-readable medium may include, but is not limited to, floppy diskettes, optical disks, compact disc read-only memories (CD-ROMs), magneto-optical disks, ROMs, random access memories (RAMs), erasable programmable read-only memories (EPROMs), electrically erasable programmable read-only memories (EEPROMs), magnetic or optical cards, flash memory, or other type of media/machine-readable medium suitable for storing electronic instructions. The machine-readable medium includes non-transitory medium, where non-transitory excludes propagation signals. For example, a processor can be connected to a non-transitory computer-readable medium that stores instructions for executing instructions by the processor.

To reduce the number of claims, certain aspects of the technology are presented below in certain claim forms, but the applicant contemplates the various aspects of the technology in any number of claim forms.

In the following description, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

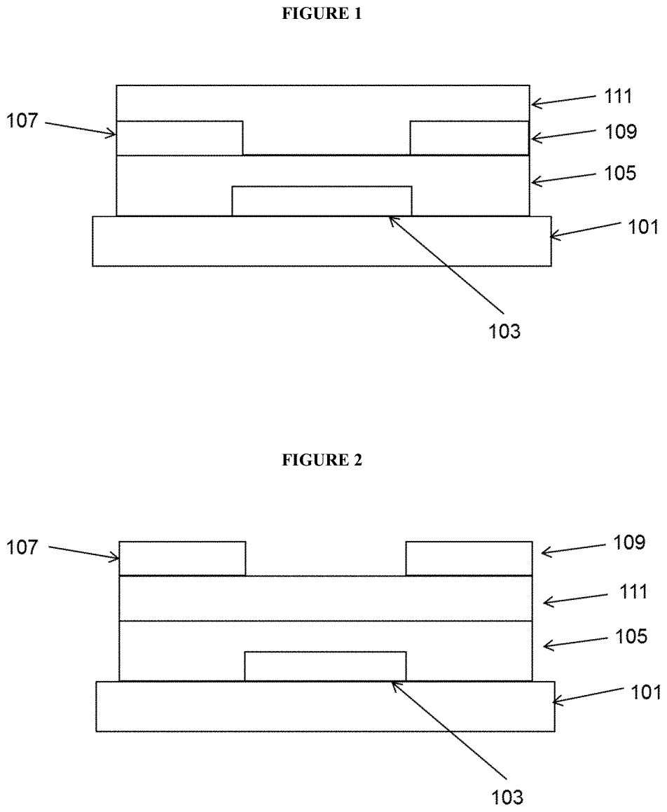

FIG. 1 is a schematic illustration of a bottom contact, bottom gate TFT (BG-TFT) gas sensor in accordance with some embodiments of the present disclosure. The bottom contact BG-TFT comprises a gate electrode 103 over a substrate 101; source electrode 107 and drain electrode 109 defining a channel; a dielectric layer 105 disposed between the gate electrode and the source and drain electrodes; and a semiconductor layer 111 extending between the source and drain electrodes and across the channel.

A layer “between” and/or “disposed between” two other layers, as described herein, may be in direct contact with each of the two layers or may be between or may be spaced apart from one or both of the two other layers by one or more intervening layers.

As used herein, a material “over” and/or “disposed over” a layer means that the material is in direct contact with the layer or is spaced apart therefrom by one or more intervening layers. As used herein, a material “on” and/or “disposed on” a layer means that the material is in direct contact with the layer.

The semiconductor layer 111 may at least partially or completely cover the source and drain electrodes. The gas sensor may be configured to provide for communication of a target gas, for example 1-MCP, through the semiconductor layer and the dielectric layer to the gate electrode. A surface of the gate electrode at the gate electrode—gate dielectric interface in communication with the target gas may comprise or consist of a conductive material having a work function which changes upon exposure of the surface to the target gas. FIG. 2 is a schematic illustration of a top-contact BG-TFT gas sensor in accordance with some embodiments of the present disclosure. The top-contact BG-TFT gas sensor is as described with reference to FIG. 1 except that the semiconductor layer 111 is between the dielectric layer 105 and the source electrode 107 and drain electrode 109.

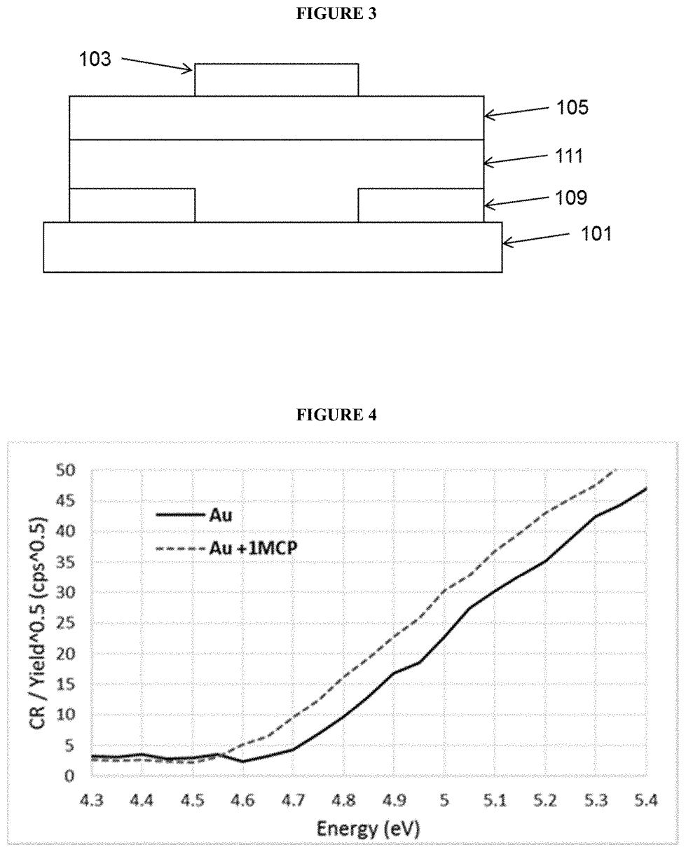

FIG. 3 is a schematic illustration of a top gate TFT gas sensor in a gas sensor system in accordance with some embodiments of the present disclosure. The top gate TFT comprises a source electrode 107 and a drain electrode 109 supported on or over a substrate 101; a semiconductor layer 111; and a dielectric layer 105 between the gate electrode 103 and the semiconductor layer. The dielectric layer 105 is between the substrate and the gate electrode 103.

Gas Sensor Measurements and Gas Identification

Certain target gases may alter the threshold voltage of a TFT, for example due to a change in the work function of a conducting material of the gate electrode at the gate electrode—gate dielectric interface which may be as a result of binding of the gas to the gate electrode at the interface. The target gas may be a gas having a dipole moment such as 1-MCP.

The gate electrode comprises a conductive material having a work function which changes upon exposure to the target gas. The conductive material may be a major component (greater than 50 wt %) of the gate electrode. The gate electrode may consist of the conductive material. The gate electrode may comprise one, two or more conductive layers with the proviso that the layer of the gate electrode adjacent to the gate dielectric comprises a conducting material having a work function which may be changed in the presence of the target gas.

The conductive material may be an elemental metal, for example gold, silver or platinum. The conductive material may be a conductive compound, for example a conducting metal oxide such as indium tin oxide. Optionally, the work function of the conducting material changes by at least 0.05 eV upon exposure to the target gas. The work function may be measured using a Riken AC2 Photoelectron Spectrometer.

In use according to some embodiments of the present disclosure, the gas sensor may be exposed to a gaseous atmosphere and the response of the sensor is measured. Optionally, the gaseous atmosphere is in an environment in which ethylene and/or 1-MCP may be present, for example an environment of a warehouse or transport container in which harvested climacteric fruits and/or cut flowers are stored and/or transported, and in which ethylene may be generated. According to some embodiments of the present disclosure, the presence of 1-MCP may be may be determined by determining a change in the current of the gas sensor.

If ethylene concentration reaches or exceeds a predetermined threshold value, which may be a predetermined value greater than 0, then 1-MCP may be released from a 1-MCP source to retard the effect of the ethylene, such as ripening of fruit or opening of flowers in the environment. The concentration of 1-MCP in such an environment is suitably no more than about 10 ppm or about 5 ppm.

Optionally, 1-MCP may be released into the atmosphere if a 1-MCP concentration derived from the gas sensor measurement falls to or below a threshold 1-MCP concentration value as determined by the gas sensor. The threshold 1-MCP concentration value may be 0 or a predetermined positive value. 1-MCP may be released automatically from a 1-MCP source or an alert or instruction may be generated to manually release 1-MCP from a 1-MCP source upon determination that 1-MCP concentration is at or below a threshold value and/or in response to a determination that ethylene concentration is at or exceeds a threshold value.

An environment in which an alkene may be present may be divided into a plurality of zones if the concentration of an alkene or alkenes may differ between zones, each zone comprising a gas sensor according to the present invention and a source of 1-MCP. For example, a warehouse may comprise a plurality of zones.

The gas sensor described herein may be a component of a gas sensor system which further comprises a reference gas sensor, optionally a TFT or chemiresistor gas sensor, to provide a baseline for measurements to take into account variables such as one or more of humidity, temperature, pressure, variation of sensor parameter measurements over time (such as variation of TFT gas sensor drain current over time), and gases other than a target gas or target gases in the atmosphere.

The reference gas sensor may be isolated from the atmosphere, for example by encapsulation of the reference gas sensor, to provide a baseline measurement which is not affected by gases in the atmosphere. The reference gas sensor may be a TFT in which the work function of the TFT gate electrode does not change in the presence of the target gas, for example an aluminium gate in the case where the target gas is 1-MCP.

The reference gas sensor may be a reference TFT having a gate electrode which is the same as the gate electrode of the TFT gas sensor wherein a surface of the gate electrode is capped to block communication of the target gas with the gate electrode surface. In some embodiments, the gate electrode is capped with a monolayer, for example a thiol monolayer.

The response of the gas sensor to background gases other than the target gases for detection, for example air or water vapour, may be measured during or prior to use to allow subtraction of the background from measurements of the gas sensor when in use.

Source and Drain Electrodes

The source and drain electrodes may be selected from a wide range of conducting materials for example a metal (e.g. gold or aluminium), metal alloy, metal compound (e.g. indium tin oxide) or conductive polymer.

In some embodiments a modification layer, optionally a monolayer, may be disposed on a surface of the source and drain electrodes. The modification layer may alter the work function of the source and drain electrodes. The modification layer may be selected to reduce contact resistance at the interface between the semiconducting layer and the source and drain electrodes. The modification layer may prevent a gas from interacting with the source and drain electrodes. In some embodiments, the source and drain electrodes are gold electrodes having a thiol monolayer disposed on a surface thereof.

Semiconductor Layer

The semiconductor layer may comprise one or more semiconductor materials. Each semiconductor layer may independently be an organic material or inorganic material. Organic semiconductors as described herein may be selected from conjugated non-polymeric semiconductors; polymers comprising conjugated groups in a main chain or in a side group thereof; and carbon semiconductors such as graphene and carbon nanotubes.

An organic semiconductor layer may comprise or consist of a semiconducting polymer and/or a non-polymeric organic semiconductor. The organic semiconductor layer may comprise a blend of a non-polymeric organic semiconductor and a polymer. Exemplary organic semiconductors are disclosed in WO 2016/001095, the contents of which are incorporated herein by reference.

The organic semiconducting layer may be deposited by any suitable technique, including evaporation and deposition from a solution comprising or consisting of one or more organic semiconducting materials and at least one solvent. Exemplary solvents include benzenes with one or more alkyl substituents, preferably one or more C₁₋₁₀ alkyl substituents, such as toluene and xylene; tetralin; and chloroform. Solution deposition techniques include coating and printing methods, for example spin coating dip-coating, slot-die coating, ink jet printing, gravure printing, flexographic printing and screen printing.

Optionally, the organic semiconducting layer of an organic thin film transistor has a thickness in the range of about 10-200 nm. Exemplary inorganic semiconductors include, without limitation, n-doped silicon; p-doped silicon; compound semiconductors, for example III-V semiconductors such as GaAs or InGaAs; doped or undoped metal oxides; doped or undoped metal sulfides; doped or undoped metal selenides; or doped or undoped metal tellurides.

Dielectric Layer

The dielectric layer of a TFT gas sensor as described herein comprises a dielectric material. Preferably, the dielectric constant, k, of the dielectric material is at least 1.8, at least 1.9, at least 2 or at least 3. The dielectric material may be organic, inorganic or a mixture thereof. Preferred inorganic materials include Si0₂, SiNx and spin-on-glass (SOG). Preferred organic materials are polymers and include insulating polymers such as poly vinylalcohol (PVA), polyvinylpyrrolidine (PVP), acrylates such as polymethylmethacrylate (PMMA) and benzocyclobutanes (BCBs), poly(vinyl phenol) (PVPh), poly(vinyl cinnamate) P(VCn), poly(vinylidene fluoride-co-hexafluoropropylene) P(VDF-HFP), P(VDF-TrFE-CTFE), poly[4,5-difluoro-2,2-bis(trifluoromethyl)-1,3-dioxole-co-tetrafluoroethylene] (AF2400 PTFE) and self-assembled monolayers, e.g. silanes, on oxide. The polymer may be crosslinkable. The insulating layer may be formed from a blend of materials or comprise a multi-layered structure. In the case of a bottom-gate device, the gate electrode may be reacted, for example oxidised, to form a dielectric material.

The dielectric material may be deposited by thermal evaporation, vacuum processing or lamination techniques as are known in the art. Alternatively, the dielectric material may be deposited from solution using, for example, spin coating or ink jet printing techniques and other solution deposition techniques discussed above. In the case of a bottom gate OTFT, the dielectric material should not be dissolved if an organic semiconductor is deposited onto it from solution. In the case of a top-gate OTFT, the organic semiconductor layer should not be dissolved if the dielectric is deposited from solution.

Techniques to avoid such dissolution include: use of orthogonal solvents for example use of a solvent for deposition of the organic semiconducting layer that does not dissolve the dielectric layer in the case of a bottom gate device or vice versa in the case of a top gate device; cross linking of the dielectric layer before deposition of the organic semiconductor layer in the case of a bottom gate device; or deposition from solution of a blend of the dielectric material and the organic semiconductor followed by vertical phase separation as disclosed in, for example, L. Qiu, et al., ADV. MATER. 20, 1141 (2008).

In some embodiments, the thickness of the dielectric layer is less than about 2 micrometres, and in some embodiments less than about 500 nm. The substrate of a sensor as described herein may be any insulating substrate, optionally glass or plastic.

Gas sensors and gas sensor systems comprising a sensor described herein may be used in detection of strained alkenes generally, optionally compounds comprising a cyclopropene or cyclobutene group, of which alkylpropenes such as 1-MCP are examples; in detection of aliphatic alkenes, optionally ethylene, propene, 1-butene or 2-butene; and/or in detection of compounds with a dipole moment, such as hydrocarbons that do not have a mirror plane bisecting a carbon-carbon bond of the hydrocarbon. In some embodiments, compounds with a dipole moment as described herein have a dipole moment of greater than 0.2 Debyes or greater than 0.3 or 0.4 Debyes.

### EXAMPLES

Effect of 1-MCP on Gold Work Function

Photoelectron spectra of the surface of a film of elemental gold before and after exposure to 1-MCP were taken using a Riken AC2 Photoelectron Spectrometer. With reference to FIG. 4, work function fell by about 0.1 eV upon exposure to 1-MCP.

### Device Example 1

A crosslinked dielectric layer (300 nm) was formed by spin-coating an insulating polymer onto a gold gate electrode supported on a PEN substrate and crosslinking by heat treatment at 180° C. for 30 minutes. A semiconducting layer (40 nm) was formed on the dielectric layer by spin-coating Semiconducting Polymer 1 from a 1,2,4-trimethylbenzene solution. Gold source and drain electrodes were formed on the semiconducting layer by evaporation.

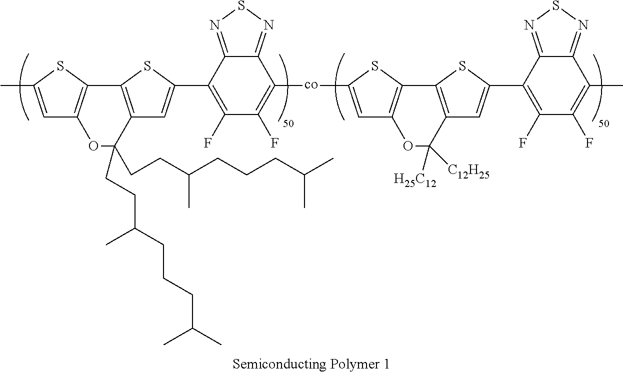

Comparative Device 1

For the purpose of comparison, a device was formed as described for Device Example 1 except that the gold gate electrode was treated with UV/ozone prior to deposition of the dielectric layer.

The response of Device Example 1 and Comparative Device 1 to exposure to an environment containing 1-MCP gas was measured by monitoring the level of the drain current as a function of time. The OTFT was driven at a constant finite voltage of Vg=Vs=−4V.

To introduce 1-MCP into the environment, 1-MCP (1/100 dilution in alpa-cyclodextrin) was added to a 1 L bottle. Humid air was bubbled through the water at a flow rate 50 cc/min). The air carried the 1-MCP through a gas tight container containing the BG-OTFT.

Device Example 1 and Comparative Device 1 operating at Vd=Vg=−4V were exposed after about 1.45 hours to 50 ppb by bubbling humid air to displace the 1-MCP.

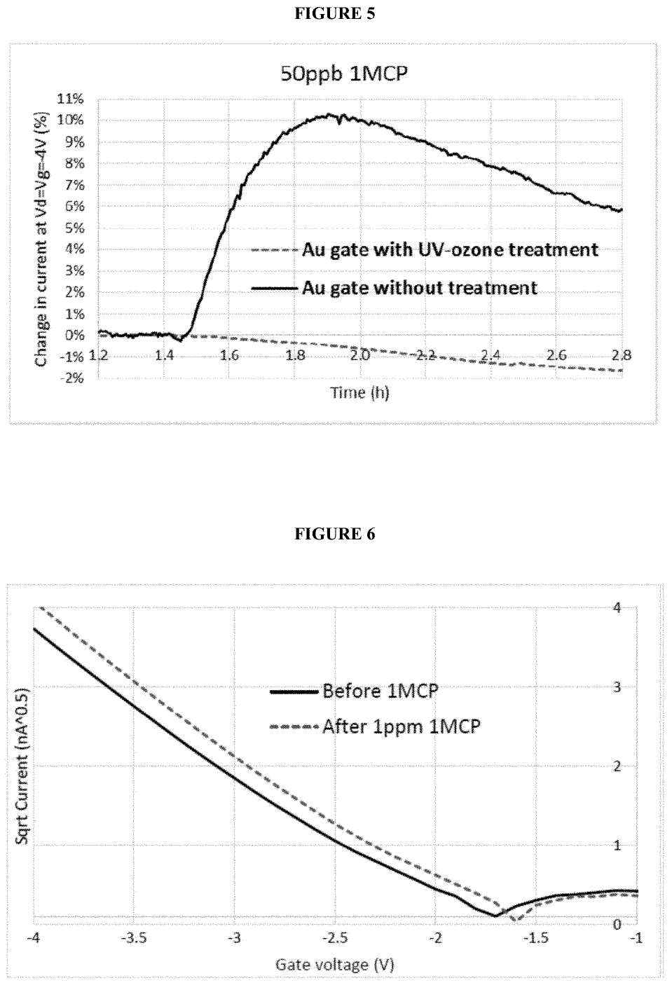

With reference to FIG. 5, drain current of Device Example 1 increased by about 10%. The drain current recovered when 1-MCP was no longer present in the gas flow. In contrast, UV/ozone treatment of Comparative Device 1 resulted in no clear change. Without wishing to be bound by any theory, it is believed that UV/ozone treatment of the gold gate electrode alters the surface of the electrode such that 1-MCP is, at least temporarily, unable to bind to the electrode surface.

FIG. 6 is a graph of the square root of drain current vs. gate voltage before and after exposure to 1-MCP. A threshold voltage shift of about +90 mV occurs upon exposure to 1-MCP.

1. A method of sensing a target gas in an environment, the method comprising:
measuring a response of a thin-film transistor gas sensor in the environment, wherein the thin-film transistor gas sensor comprises:
a semiconducting layer comprising an organic semiconductor;
a source electrode and a drain electrode configured to define a channel in the semiconducting layer;
a gate electrode; and
a dielectric layer disposed between the gate electrode and the semiconductor layer, wherein the gate electrode comprises a conducting layer having a surface in direct contact with the dielectric layer and the surface comprises a work function which changes upon exposure to the target gas.

2. The method of claim 1, wherein the thin-film transistor gas sensor is a bottom-gate thin film transistor gas sensor.

3. The method of claim 1, wherein the target gas is 1-methylcyclopropene.

4. The method of claim 1, wherein the gate electrode comprises elemental gold.

5. The method of claim 4, wherein the elemental gold is a major component by weight of the gate electrode.

6. The method of claim 4, wherein the gate electrode consists of elemental gold.

7. The method of claim 1, wherein the dielectric layer comprises an organic material.

8. The method of claim 1, wherein the thin film transistor gas sensor is comprised in a gas sensor system which further comprises a reference thin film transistor.

9. The method of claim 8, wherein the reference thin film transistor comprises a gate electrode having a work function that does not change upon exposure to the target gas.

10. A thin film transistor gas sensor for detecting and/or measuring a concentration of a target gas in an atmosphere, comprising:
a semiconducting layer comprising an organic semiconductor;
a source electrode and a drain electrode configured to define a channel in the semiconducting layer;
a gate electrode;
a dielectric layer disposed between the gate electrode and the semiconductor layer, wherein the gate electrode comprises a conducting layer having a surface in direct contact with the dielectric layer, wherein a work function of the surface is configured to change when contacted by the target gas; and
a processor configured to process the presence and/or the concentration of the target from an output of the thin film transistor gas sensor.

11. The thin film transistor gas sensor of claim 10, wherein the target gas is 1-methylcyclopropene.

12. The thin film transistor gas sensor of claim 10, wherein the gate electrode comprises elemental gold.

13. The thin film transistor gas sensor of claim 12, wherein the elemental gold is a major component by weight of the gate electrode.

14. A thin film transistor gas sensor according to claim 12, wherein the gate electrode consists of elemental gold.

15. The thin film transistor gas sensor of claim 10, wherein the dielectric layer comprises an organic material.

16. A gas sensor system comprising the thin film transistor gas sensor of claim 10 and a reference thin film transistor.

17. The gas sensor system of claim 16, wherein the reference thin film transistor comprises a gate electrode having a work function that does not change upon exposure to the target gas.
